(19) United States
(12) Patent Application Publication
(10) Pub. No.: US 2026/0130086 A1
(43) Pub. Date: May 7, 2026

(54) ENHANCING LUMINESCENT PROPERTIES OF VAPOR-DEPOSITED PEROVSKITE FILMS THROUGH VAPOR EXPOSURE

(71) Applicant: Jian Li, Tempe, AZ (US)

(72) Inventor: Jian Li, Tempe, AZ (US)

(21) Appl. No.: 19/377,995

(22) Filed: Nov. 3, 2025

Related U.S. Application Data
(60) Provisional application No. 63/715,416, filed on Nov. 1, 2024.

(51) Int. Cl. H10K 59/38; C09K 11/66; H10K 59/12

(52) U.S. Cl. CPC H10K 59/38; C09K 11/665; H10K 59/1201

(57) ABSTRACT

A modified perovskite material includes a vapor-deposited material including an ABX₃ metal halide perovskite defining vacancies and a multiplicity of molecules, each coupled to at least one atom in the vapor-deposited perovskite material or filling a vacancy in the vapor-deposited perovskite material. The vapor-deposited perovskite material includes an ABX₃ metal halide perovskite defining vacancies where A and B are cations, X₃ is ClₓBr_{y}I_{z}, and x+y+z=3. Each of x, y, and z is independently greater than or equal to 0 and less than or equal to 3.

### CROSS-REFERENCE TO RELATED APPLICATION

This application claims the benefit of U.S. Patent Application No. 63/715,416 filed on Nov. 1, 2024, which is incorporated by reference herein in its entirety.

### STATEMENT OF GOVERNMENT SUPPORT

This invention was made with government support under 2329871 awarded by the National Science Foundation. The government has certain rights in the invention.

### TECHNICAL FIELD

This invention relates to metal halide perovskite films enhanced through exposure to solvent vapor or air, and to their use as color conversion material.

### BACKGROUND

Defects in metal halide perovskites, ranging from intrinsic point defects to surface imperfections introduced during the fabrication process, limit their photoluminescence (PL) efficiency and stability. Passivation of imperfections can lead to improved efficiency and stability.

### SUMMARY

This disclosure describes metal halide ABX₃ perovskite materials based on (CsPbClₓBr_{y}I_{z}; x+y+z=3) as source material for spectrally stable color conversion films. Optical properties of perovskite films are enhanced through controlled exposure to vapor. Vacancy defects are filled with vapor molecules through chemical bonding between perovskite ions and coordinating functional groups or atoms of the vapor compounds. A blue organic light-emitting diode (OLED)-based full color display that incorporates the vapor-deposited perovskite is also described.

In a first general aspect, a modified perovskite material includes a vapor-deposited perovskite material including an ABX₃ metal halide perovskite defining vacancies, wherein A and B are cations, X₃ is ClₓBr_{y}I_{z}, and x+y+z=3, wherein each of x, y, and z is independently greater than or equal to 0 and less than or equal to 3; and a multiplicity of molecules, each coupled to at least one atom in the vapor-deposited perovskite material or filling a vacancy in the vapor-deposited perovskite material.

Implementations of the first general aspect can include one or more of the following features.

In some cases, A is cesium (Cs) or tetraalkyl ammonium. Each alkyl of the tetraalkyl ammonium can be independently selected from alkyl groups having 1-6 carbon atoms. In some cases, B is lead (Pb) or tin (Sn). In some implementations, the multiplicity of molecules include H₂O or O₂. In certain cases, the multiplicity of molecules include organic ligands selected from monodentate ligands, bidentate ligands, and tridentate ligands and their analogs. Each organic ligand of the multiplicity of molecules can include one or more functional groups independently selected from oxo, hydroxyl, thiol, nitro, cyanide, isocyanide, sulfinyl, mercapto, sulfo, carboxyl, hydrazine, amino, monoalkylamino, dialkylamino, monoarylamino, diarylamino, alkoxy, aryloxy, haloalkyl, ester, amide, alkoxycarbonyl, acylamino, alkoxycarbonylamino, aryloxycarbonylamino, sulfonylamino, sulfamoyl, carbamoyl, alkylthio, ureido, phosphoramide, or silyl functional groups, or any conjugate or combination thereof. In some cases, the monodentate ligands include n-butanol. In some implementations, the bidentate ligands include diacetone alcohol. In some cases, the modified perovskite material includes up to 2 wt % or up to 5 wt % of the multiplicity of molecules. In certain cases, the ABX₃ metal halide perovskite is doped with A site replacements, B site replacements, or both. The A site replacements can include Li⁺, Na⁺, K⁺, Rb⁺, Cs⁺, and their monoionic analogs, or any combination thereof and the B site replacements can include Mg²⁺, Ca²⁺, Mn²⁺, Ni²⁺, Cu²⁺, Zn²⁺, and their bivalent analogs, or any combination thereof. An intensity of a photoluminescence peak of the modified perovskite material can exceed an intensity of a photoluminescence peak of the vapor deposited perovskite material by at least a factor of five.

In a second general aspect, fabricating the modified perovskite material of the first general aspect includes vapor depositing a perovskite precursor on a substrate to yield the vapor-deposited perovskite material, wherein the vapor-deposited perovskite material includes an ABX₃ metal halide perovskite defining vacancies, wherein A and B are cations, X₃ is ClₓBr_{y}I_{z}, and x+y+z=3, wherein each of x, y, and z is independently greater than or equal to 0 and less than or equal to 3, contacting the vapor-deposited perovskite material with a vapor including a multiplicity of molecules; and coupling molecules of the multiplicity of molecules to at least one atom in the vapor-deposited perovskite material, filling vacancies in the vapor-deposited perovskite material with molecules of the multiplicity of molecules, or both.

Implementations of the second general aspect can include one or more of the following features.

In some cases, A is Cs or tetraalkyl ammonium. Each alkyl of the tetraalkyl ammonium can be independently selected from alkyl groups having 1-6 carbon atoms. In some cases, B is Pb or Sn. In some implementations, contacting includes exposing the vapor-deposited perovskite material with the vapor for at least two minutes. The multiplicity of molecules can include H₂O or O₂. In certain cases, the multiplicity of molecules include organic ligands selected from monodentate ligands, bidentate ligands, and tridentate ligands and their analogs. Each organic ligand of the multiplicity of molecules can include one or more functional groups independently selected from oxo, hydroxyl, thiol, nitro, cyanide, isocyanide, sulfinyl, mercapto, sulfo, carboxyl, hydrazine, amino, monoalkylamino, dialkylamino, monoarylamino, diarylamino, alkoxy, aryloxy, haloalkyl, ester, amide, alkoxycarbonyl, acylamino, alkoxycarbonylamino, aryloxycarbonylamino, sulfonylamino, sulfamoyl, carbamoyl, alkylthio, ureido, phosphoramide, or silyl functional groups, or any conjugate or combination thereof. In some cases, the monodentate ligands include n-butanol. In some implementations, the bidentate ligands include diacetone alcohol. The modified perovskite material can include up to 2 wt % or up to 5 wt % of the multiplicity of molecules. In certain cases, the ABX₃ metal halide perovskite is doped with A site replacements, B site replacements, or both. The A site replacements include Li²⁺, Na²⁺, K²⁺, Rb²⁺, Cs²⁺ and their monoionic analogs, or any combination thereof and the B site replacements can include Mg²⁺, Ca²⁺, Mn²⁺, Ni²⁺, Cu²⁺, Zn²⁺ and their bivalent analogs, or any combination thereof.

In a third general aspect, a full color display includes an array of red, green, and blue pixels, wherein each pixel includes: an anode layer, a hole injection layer, a hole transporting layer, an electron blocking layer, a blue emissive layer, a blue hole blocking layer, an electron transporting layer, and a cathode layer, wherein the red pixels further include a red color conversion material including the modified perovskite material of the first general aspect and the green pixels further include a green color conversion material including the modified perovskite material of the first general aspect.

Implementations of the third general aspect can include one or more of the following features. In some cases, the first general aspect further includes a red color filter on a surface of the red color conversion material, a green color filter on a surface of the green color conversion material, or both.

In a fourth general aspect, fabricating the full color display of the third general aspect includes forming an array of blue pixels, each blue pixel including: an anode layer, a hole injection layer, a hole transporting layer, an electron blocking layer, a blue emissive layer, a blue hole blocking layer, an electron transporting layer; and a cathode layer, and disposing the red color conversion material on a top of selected semi-transparent electrode (cathode or anode) of a first subset of the blue pixels, and disposing the green color conversion material on a top of selected semi-transparent electrode (cathode or anode) of a second subset of the blue pixels.

Implementations of the fourth general aspect can include one or more of the following features. In some cases, the blue pixels are formed in the absence of a shadow mask. Each layer of the blue pixels can be fabricated as a common layer including the same components. In some cases, disposing the red color conversion material on the first subset of the blue pixels includes a shadow mask controlled vapor deposition process. In certain cases, disposing the green color conversion material on the second subset of the blue pixels includes a shadow mask controlled vapor deposition process. The fourth general aspect can further include disposing a red filter on a surface of the red color conversion material, a green filter on a surface of the green color conversion material, or both. In some cases, disposing includes a photolithographic process.

In a fifth general aspect, fabricating the full color display of the third general aspect includes disposing the red color conversion material in first discrete regions on a substrate, thereby defining a location of red pixels, disposing the green color conversion material in second discrete regions on the substrate, thereby defining a location of green pixels, and forming blue organic light emitting diodes on the first discrete regions, the second discrete regions, and third discrete regions, wherein the third discrete regions define a location of blue pixels.

The details of one or more embodiments of the subject matter of this disclosure are set forth in the accompanying drawings and the description. Other features, aspects, and advantages of the subject matter will become apparent from the description, the drawings, and the claims.

### BRIEF DESCRIPTION OF DRAWINGS

FIG. 1 shows possible elements for ABX₃ materials like CsPbBr₃ based perovskite materials. A site replacement includes Li, Na, K ions and other organic based analogs, and B site replacement includes Mg²⁺, Ca²⁺, Mn²⁺, Ni²⁺, Cu²⁺, Zn²⁺ ions and other organic based analogs.

FIG. 2 is a schematic illustration showing low photoluminescence (PL) efficiency of solution-processed or vapor-deposition perovskite film, where the defects from A-site and/or B-site cause nonradiative recombination.

FIG. 3 is a schematic illustration showing improved PL efficiency of a perovskite film after organic vapor exposure due at least in part to the defect suppression through the coordination/chemical bonding of monodentate vapor molecules.

FIG. 4 is a schematic illustration showing improved PL efficiency of a perovskite film after organic vapor exposure due at least in part to the defect suppression through the coordination/chemical bonding of bidentate vapor molecules.

FIG. 5 shows the chemical structures of exemplary monodentate vapor molecules n-butanol and bidentate vapor molecules diacetone alcohol.

FIG. 6 is a schematic illustration showing improved photoluminescence efficiency of perovskite film after air exposure due at least in part to the defect suppression through the coordination/chemical bonding of oxygen atoms from oxygen and/or H₂O molecules.

FIG. 7A is a schematic illustration of red/green/blue (RGB) organic light-emitting diode (OLED) based full color displays. FIG. 7B is a schematic illustration of blue OLED based full color displays. FIG. 7C is a schematic illustration showing RGB OLED based full color displays, where red, green, and blue OLED pixels are individually and separately deposited on the substrate through shadow masks.

FIG. 8 is a schematic illustration of an example blue OLED based full color display.

FIG. 9 is a schematic illustration showing the layers of a blue OLED based full color display.

FIG. 10 shows PL spectra of fresh (open square) and diacetone alcohol vapor exposed (filled square) 15 nm 10% CsBr:10% MgBr₂:CsPbBr₃ film on the quartz substrates with cover glass encapsulated inside nitrogen filled glove box.

FIG. 11 shows PL spectra of fresh (open square) and diacetone alcohol vapor exposed (filled square) 15 nm 10% MgBr₂:CsPbBr₃ film on the quartz substrates with cover glass encapsulated inside nitrogen filled glove box.

FIG. 12 shows a PL spectrum of air exposed 15 nm 10% CsBr:10% MgBr₂:CsPbBr₃ film.

### DETAILED DESCRIPTION

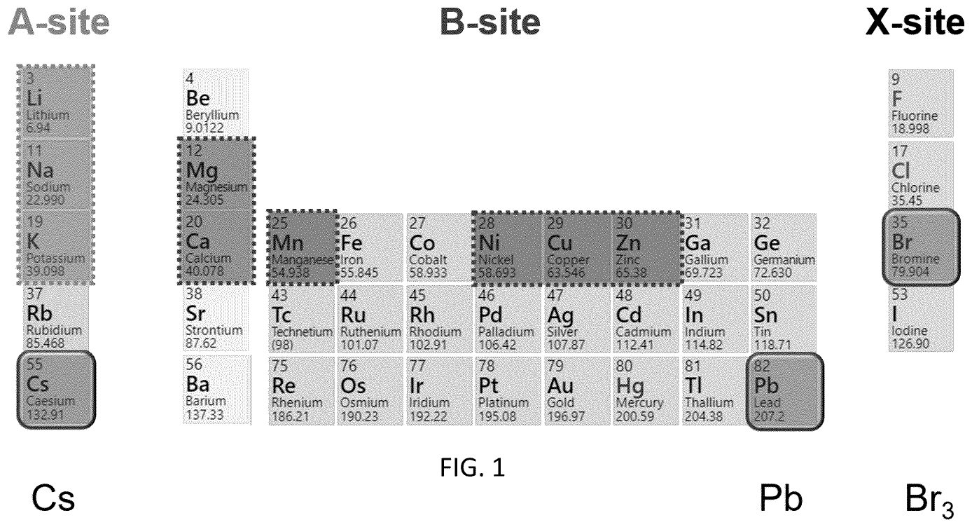

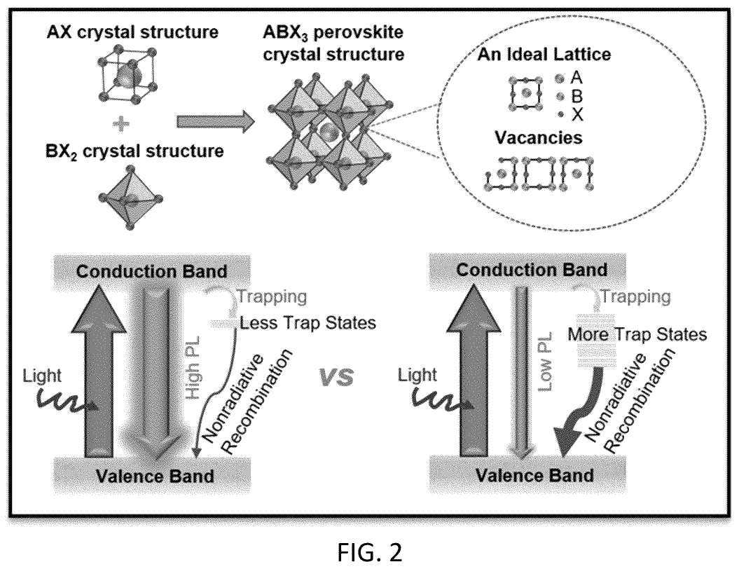

This disclosure describes a series of metal halide ABX₃ perovskite materials based on (CsPbClₓBr_{y}I_{z}; x+y+z=3) as source material for spectrally stable color conversion films. FIG. 1 shows suitable example elements for ABX₃ materials (e.g., CsPbBr₃ based perovskite materials). The metal halide perovskites described herein demonstrate photoluminescence efficiency, and provide enhanced color purity and long-term stability. These perovskites perform more efficiently as light emitters at least in part because they lack lattice vacancies known to reduce efficiency, as shown in FIG. 2.

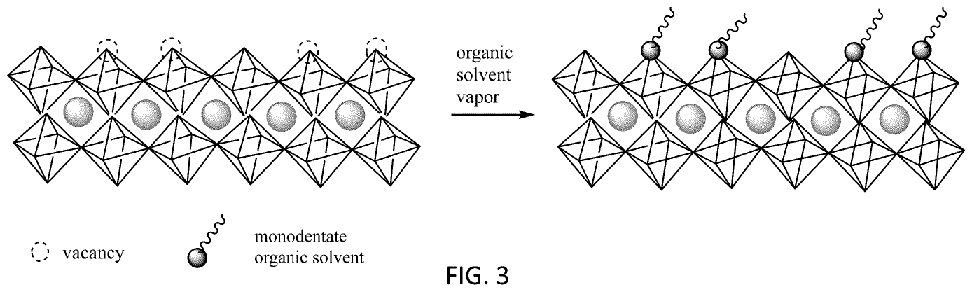

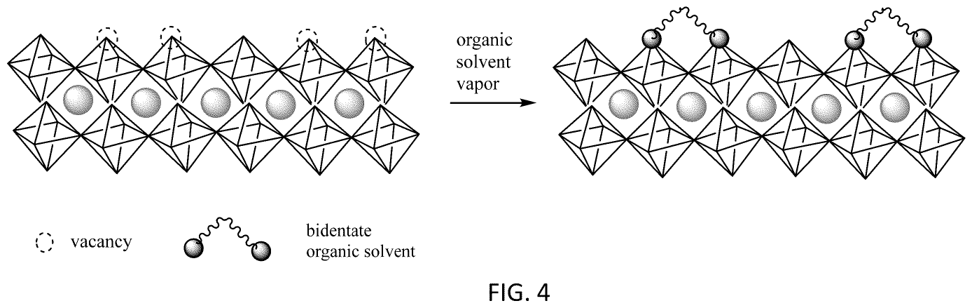

The optical properties of vapor-deposited perovskite films described herein are enhanced through controlled exposure to vapor molecules or air. The vacancy defects are filled with vapor molecules through chemical bonding between perovskite ions and coordinating functional groups or atoms from the vapor molecules, as shown in FIGS. 3 and 4.

A modified perovskite material includes a vapor-deposited material including an ABX₃ metal halide perovskite defining vacancies and a multiplicity of molecules, each coupled to at least one atom in the vapor-deposited perovskite material or filling a vacancy in the vapor-deposited perovskite material. The vapor-deposited perovskite material typically includes an ABX₃ metal halide perovskite defining vacancies where A and B are cations, X₃ is ClₓBr_{y}I_{z}, and x+y+z=3. Each of x, y, and z can be an integer or non-integer, and is independently greater than or equal to 0 and less than or equal to 3. For use in full color displays, x, y, and z are typically integers.

Suitable examples of A include cesium (Cs) or tetraalkyl ammonium. Each alkyl of the tetraalkyl ammonium is independently selected from alkyl groups having 1-6 carbon atoms (e.g., 2-4) carbon atoms. In some examples, the tetraalkyl ammonium includes ethyl, butyl, or any combination thereof. Suitable examples of B include lead (Pb) or tin (Sn). In some implementations, the multiplicity of molecules includes H₂O, O₂, or a combination thereof.

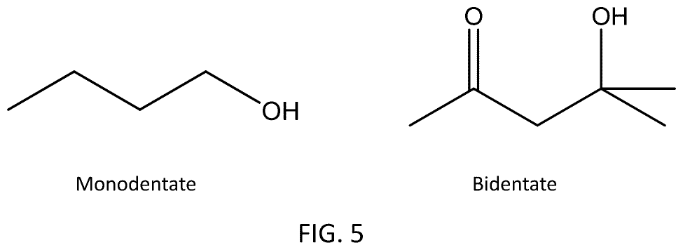

In some examples, the multiplicity of molecules include organic ligands selected from monodentate ligands, bidentate ligands, and tridentate ligands and their analogs. A suitable example of a monodentate ligand includes n-butanol. A suitable example of a bidentate ligand includes diacetone alcohol. Chemical structures of these ligand examples are shown in FIG. 5. Each organic ligand of the multiplicity of molecules typically includes one or more functional groups independently selected from oxo, hydroxyl, thiol, nitro, cyanide, isocyanide, sulfinyl, mercapto, sulfo, carboxyl, hydrazine, amino, monoalkylamino, dialkylamino, monoarylamino, diarylamino, alkoxy, aryloxy, haloalkyl, ester, amide alkoxycarbonyl, acylamino, alkoxycarbonylamino, aryloxycarbonylamino, sulfonylamino, sulfamoyl, carbamoyl, alkylthio, ureido, phosphoramide, silyl, or any conjugate or combination thereof. In some examples, the vapor molecules have one or more structural elements independently selected from alkyl, haloalkyl, aralkyl, aryl, cycloalkyl, cycloalkenyl, heterocyclyl, heteroaryl, alkenyl, and alkynyl. In some examples, bonding of the ligands to perovskite ions occurs through exposure to air.

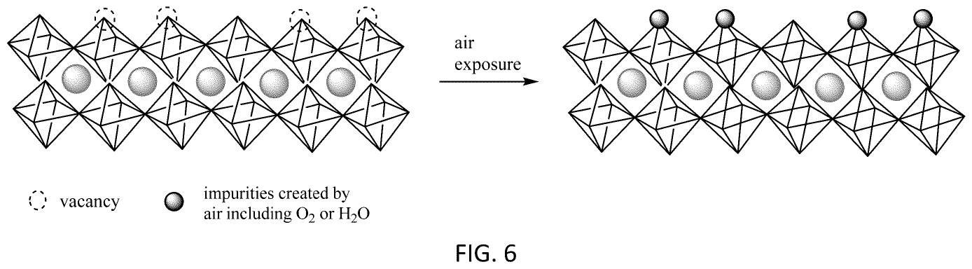

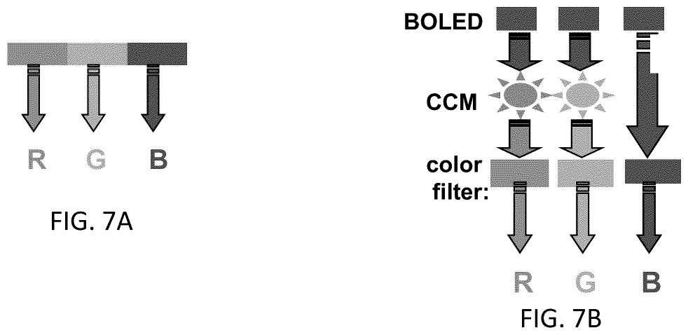

FIG. 6 is a schematic diagram showing that after exposure to air, the vacancy defects are filled with oxygen atoms through chemical bonding between perovskite ions and oxygen or water molecules. In some cases, the modified perovskite material includes up to 2 wt % or up to 5 wt % of the multiplicity of molecules.

The ABX₃ metal halide perovskite can be doped with A site replacements, B site replacements, or both. Suitable examples of A site replacements include Li⁺, Na⁺, K⁺, Rb⁺, Cs⁺, and their monoionic analogs, or any combination thereof. Suitable examples of B site replacements include Mg²⁺, Ca²⁺, Mn²⁺, Ni²⁺, Cu²⁺, Zn²⁺, and their bivalent analogs or any combination thereof. In some implementations, an intensity of a photoluminescence peak of the modified perovskite material exceeds an intensity of a photoluminescence peak of the vapor deposited perovskite material by at least a factor of five.

Fabricating a modified perovskite material includes vapor depositing a perovskite precursor on a substrate to yield the vapor-deposited perovskite material, contacting the vapor-deposited perovskite material with a vapor including a multiplicity of molecules, and coupling molecules of the multiplicity of molecules to at least one atom in the vapor-deposited perovskite material, filling vacancies in the vapor-deposited perovskite material with molecules of the multiplicity of molecules, or both. The vapor-deposited perovskite material typically includes an ABX₃ metal halide perovskite defining vacancies where A and B are cations, X₃ is ClₓBr_{y}I_{z}, and x+y+z=3. Each of x, y, and z can be an integer or non-integer, and is independently greater than or equal to 0 and less than or equal to 3.

Suitable examples of A include Cs or tetraalkyl ammonium. Each alkyl of the tetraalkyl ammonium is independently selected from alkyl groups having 1-6 carbon atoms (e.g., 2-4 carbon atoms). In some examples, the tetraalkyl ammonium is ethyl, butyl, or any combination thereof. Suitable examples of B include Pb or Sn. In some implementations, the multiplicity of molecules include H₂O or O₂.

Contacting the vapor-deposited perovskite material with the vapor typically includes exposing the vapor-deposited perovskite material with the vapor for at least two minutes. The multiplicity of molecules can include organic ligands selected from monodentate ligands, bidentate ligands, and tridentate ligands. Each organic ligand of the multiplicity of molecules typically includes one or more functional groups independently selected from oxo, hydroxyl, thiol, nitro, cyanide, isocyanide, sulfinyl, mercapto, sulfo, carboxyl, hydrazine, amino, monoalkylamino, dialkylamino, monoarylamino, diarylamino, alkoxy, aryloxy, haloalkyl, ester, amide, alkoxycarbonyl, acylamino, alkoxycarbonylamino, aryloxycarbonylamino, sulfonylamino, sulfamoyl, carbamoyl, alkylthio, ureido, phosphoramide, or silyl functional groups, or any conjugate or combination thereof. A suitable example of a monodentate ligand includes n-butanol. A suitable example of a bidentate ligand includes diacetone alcohol. In some cases, the multiplicity of molecules account for up to 2 wt % or up to 5 wt % of the modified perovskite material.

The ABX₃ metal halide perovskite can be doped with A site replacements, B site replacements, or both. Suitable examples of A site replacements include Li⁺, Na⁺, K⁺, Rb⁺, Cs⁺, and their monoionic analogs, or any combination thereof. Suitable examples of B site replacements include Mg²⁺, Ca²⁺, Mn²⁺, Ni²⁺, Cu²⁺, Zn²⁺, and their bivalent analogs or any combination thereof.

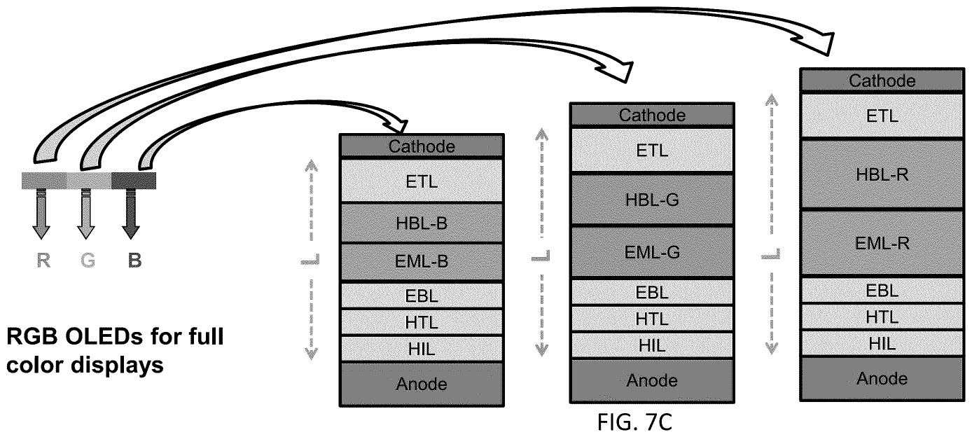

The vapor-deposited perovskite films described herein can be used in the fabrication of colored display output devices such as computer monitors, televisions, and displays on mobile phones. In red/green/blue (RGB) format, each pixel of the display is typically a controlled mix of red, green, and blue to show a blend of these colors in that pixel. This pixel surface can be achieved by using three different colors of photodiode array materials or a blue based photodiode array configured with a color conversion material that alters the output color of each photodiode to either red or green, as shown in FIGS. 7A and 7B. Using three different colors of photodiode array materials can involves multiple shadow masking procedures. For individual red, green, and blue OLEDs, a cavity device structure is typically present, leading to various layer thicknesses for red, green, and blue OLEDs, as shown in FIG. 7C. The anode layer, hole injection layer (HIL), hole transporting layer (HTL), electron blocking layer (EBL), electron transporting layer (ETL), and cathode layer can be a common layer or the same layer for all of RGB OLED pixels, while blue emissive layer (EML), blue hole blocking layer (HBL or prime), green EML, green HBL, red EML, and red HBL are deposited individually and separately through shadow mask controlled vapor deposition processes.

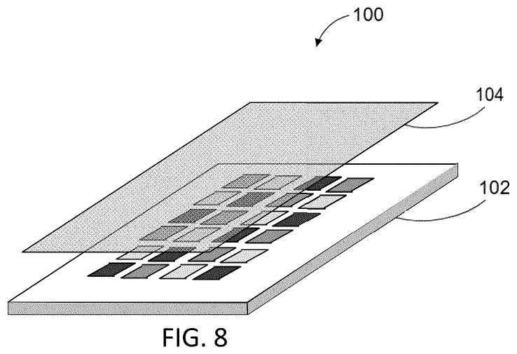

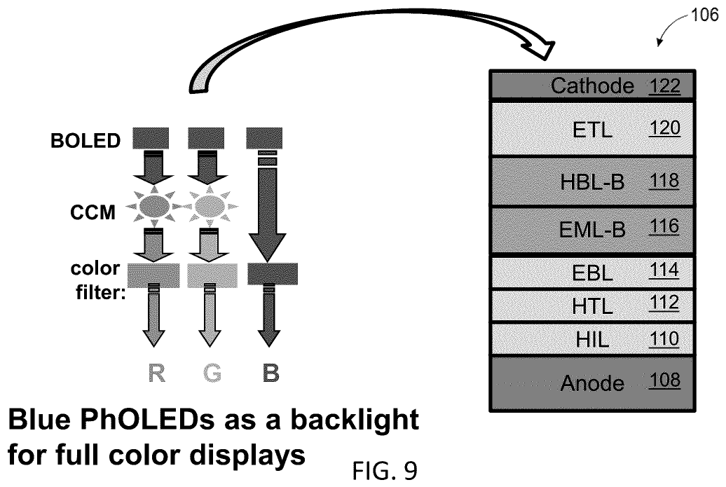

FIG. 8 is a schematic diagram of an example full color display 100 including an array of red, green, and blue pixels 102. In some cases, a shadow mask 104 is used. FIG. 9 is a schematic diagram showing the layers of a pixel 106 in the array of red, green, and blue pixels 102.

Referring to FIG. 9, in the array of red, green, and blue pixels 102, each pixel 106 includes an anode layer 108, a hole injection layer 110, a hole transporting layer 112, an electron blocking layer 114, a blue emissive layer 116, a blue hole blocking layer 118, an electron transporting layer 120, and a cathode layer 122. The red pixels further include a red color conversion material including a modified perovskite material and the green pixels further include a green color conversion material including the modified perovskite material. The full color display 100 can further include a red color filter on a surface of the red color conversion material, a green color filter on a surface of the green color conversion material, or both.

In some cases, fabricating a full color display includes forming an array of blue pixels, disposing the red color conversion material on a top of selected semi-transparent electrode (cathode or anode) of a first subset of the blue pixels, and disposing the green color conversion material on a top of selected semi-transparent electrode (cathode or anode) of a second subset of the blue pixels. Each blue pixel includes an anode layer, a hole injection layer, a hole transporting layer, an electron blocking layer, a blue emissive layer, a blue hole blocking layer, an electron transporting layer, and a cathode layer.

Disposing the green color conversion material on top of the selected semi-transparent electrode can be achieved with a photolithographic process. The blue pixels can be formed in the absence of a shadow mask. Each layer of the blue pixels can be fabricated as a common layer including the same components. Disposing the red color conversion material on the first subset of the blue pixels can include a shadow mask controlled vapor deposition process. Disposing the green color conversion material on the second subset of the blue pixels can include a shadow mask controlled vapor deposition process. In some cases, fabricating the full color display further includes disposing a red filter on a surface of the red color conversion material, a green filter on a surface of the green color conversion material, or both.

In some implementations, fabricating a full color display includes disposing the red color conversion material in first discrete regions on a substrate, thereby defining a location of red pixels; disposing the green color conversion material in second discrete regions on the substrate, thereby defining a location of green pixels; and forming blue organic light emitting diodes on the first discrete regions, the second discrete regions, and third discrete regions, wherein the third discrete regions define a location of blue pixels.

### EXAMPLES

### Example 1. Doping of 10% CsBr:10% MgBr₂:CsPbBr₃ Perovskite Films on the Quartz Substrates with Diacetone Alcohol Vapor

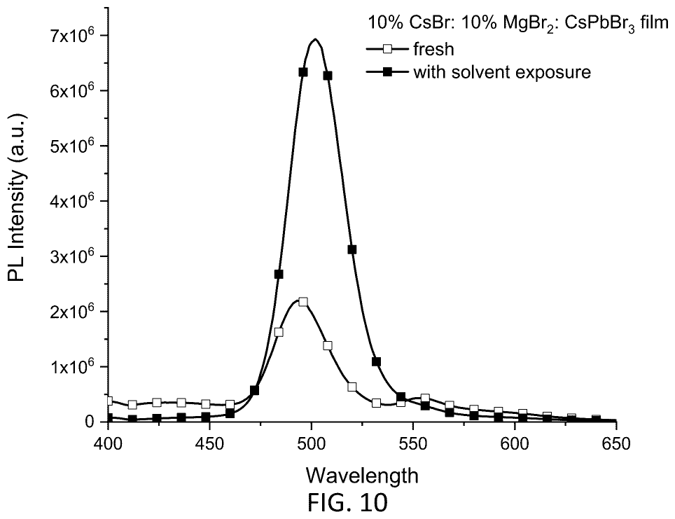

A 15 nm thick film of 10% CsBr:10% MgBr₂:CsPbBr₃ quartz substrate with cover glass encapsulated inside nitrogen filled glove box was exposed to room temperature vaporized diacetone alcohol for 2 minutes in a nitrogen atmosphere. The photoluminescence (PL) spectra before and after exposure to diacetone alcohol vapor are shown in FIG. 10. Doping with the bidentate organic compound diacetone alcohol showed enhancement in the emission signal.

### Example 2. Doping of 10% MgBr:CsPbBr₃ Perovskite Films on the Quartz Substrates with Diacetone Alcohol Vapor

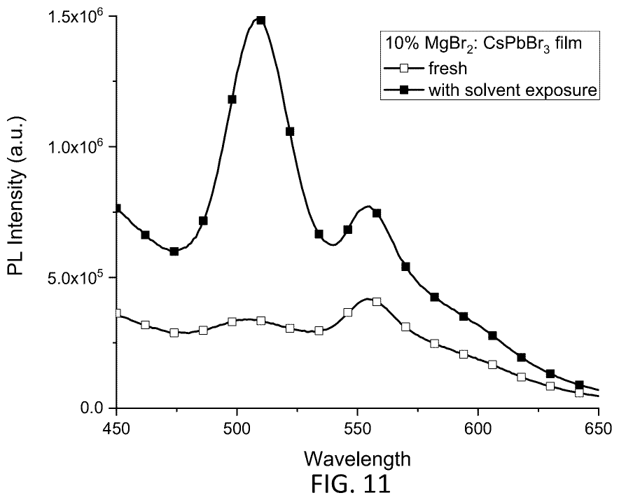

A 15 nm thick film of 10% MgBr₂:CsPbBr₃ quartz substrate with cover glass encapsulated inside nitrogen filled glove box was exposed to room temperature vaporized diacetone alcohol for 2 minutes in a nitrogen atmosphere. The PL spectra before and after exposure to diacetone alcohol vapor are shown in FIG. 11. Doping with the bidentate organic compound diacetone alcohol showed enhancement in the emission signal.

### Example 3. Doping of 10% CsBr:10% MgBr₂:CsPbBr₃ Perovskite Film on Quartz Substrate with Oxygen and/or Water Molecules

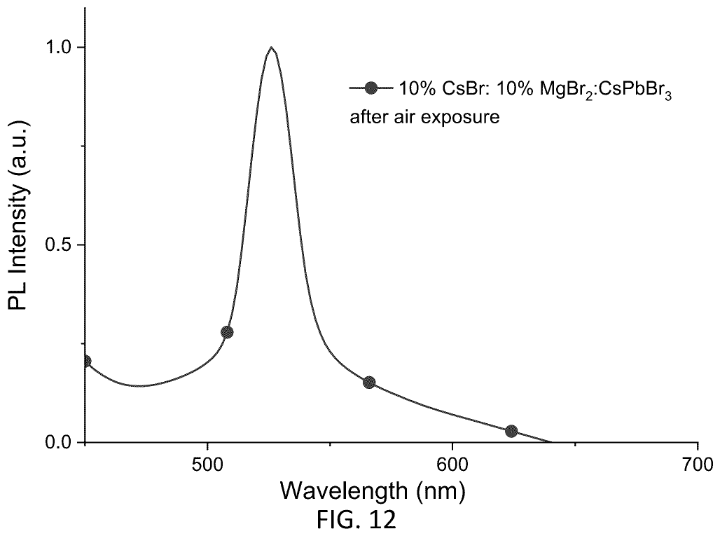

A 15 nm thick film of 10% CsBr:10% MgBr₂:CsPbBr₃ on quartz substrate with cover glass was exposed to air. The photoluminescence (PL) spectra after exposure to air is shown in FIG. 12.

Particular embodiments of the subject matter have been described. Other embodiments, alterations, and permutations of the described embodiments are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results.

Accordingly, the previously described example embodiments do not define or constrain this disclosure. Other changes, substitutions, and alterations are also possible without departing from the spirit and scope of this disclosure.

What is claimed is:

1. A modified perovskite material comprising:
a vapor-deposited perovskite material comprising an ABX₃ metal halide perovskite defining vacancies, wherein A and B are cations, and X₃ comprises ClₓBr_{y}I_{z}, x+y+z=3, wherein each of x, y, and z is independently greater than or equal to 0 and less than or equal to 3; and
a multiplicity of molecules, each coupled to at least one atom in the vapor-deposited perovskite material or filling a vacancy in the vapor-deposited perovskite material.

2. The modified perovskite material of claim 1, wherein A comprises Cs or tetraalkyl ammonium.

3. The modified perovskite material of claim 2, wherein each alkyl of the tetraalkyl ammonium is independently selected from alkyl groups having 1-6 carbon atoms.

4. The modified perovskite material of claim 1, wherein B comprises Pb or Sn.

5. The modified perovskite material of claim 1, wherein the multiplicity of molecules comprise H₂O or O₂.

6. The modified perovskite material of claim 1, wherein the multiplicity of molecules comprise organic ligands selected from monodentate ligands, bidentate ligands, and tridentate ligands and their analogs.

7. The modified perovskite material of claim 6, wherein each organic ligand of the multiplicity of molecules comprises one or more functional groups independently selected from oxo, hydroxyl, thiol, nitro, cyanide, isocyanide, sulfinyl, mercapto, sulfo, carboxyl, hydrazine, amino, monoalkylamino, dialkylamino, monoarylamino, diarylamino, alkoxy, aryloxy, haloalkyl, ester, amide, alkoxycarbonyl, acylamino, alkoxycarbonylamino, aryloxycarbonylamino, sulfonylamino, sulfamoyl, carbamoyl, alkylthio, ureido, phosphoramide, or silyl functional groups, or any conjugate or combination thereof.

8. The modified perovskite material of claim 6, wherein the monodentate ligands comprise n-butanol.

9. The modified perovskite material of claim 6, wherein the bidentate ligands comprise diacetone alcohol.

10. The modified perovskite material of claim 1, wherein the modified perovskite material comprises up to 2 wt % or up to 5 wt % of the multiplicity of molecules.

11. The modified perovskite material of claim 1, wherein the ABX₃ metal halide perovskite is doped with A site replacements, B site replacements, or both.

12. The modified perovskite material of claim 11, wherein the A site replacements comprise Li⁺, Na⁺, K⁺, Rb⁺, Cs⁺, and their monoionic analogs, or any combination thereof and wherein the B site replacements comprise Mg²⁺, Ca²⁺, Mn²⁺, Ni²⁺, Cu²⁺, Zn²⁺, and their bivalent analogs, or any combination thereof.

13. The modified perovskite material of claim 1, wherein an intensity of a photoluminescence peak of the modified perovskite material exceeds an intensity of a photoluminescence peak of the vapor deposited perovskite material by at least a factor of five.

14. A method of fabricating the modified perovskite material of claim 1, the method comprising:
vapor depositing a perovskite precursor on a substrate to yield the vapor-deposited perovskite material, wherein the vapor-deposited perovskite material comprises an ABX₃ metal halide perovskite defining vacancies, wherein A and B are cations, and X₃ comprises ClₓBr_{y}I_{z}, and x+y+z=3, wherein each of x, y, and z is independently greater than or equal to 0 and less than or equal to 3;
contacting the vapor-deposited perovskite material with a vapor comprising a multiplicity of molecules; and
coupling molecules of the multiplicity of molecules to at least one atom in the vapor-deposited perovskite material, filling vacancies in the vapor-deposited perovskite material with molecules of the multiplicity of molecules, or both.

15. The method of claim 14, wherein A comprises Cs or tetraalkyl ammonium.

16. The method of claim 15, wherein each alkyl of the tetraalkyl ammonium is independently selected from alkyl groups having 1-6 carbon atoms.

17. The method of claim 14, wherein B comprises Pb or Sn.

18. The method of claim 14, wherein contacting comprises exposing the vapor-deposited perovskite material with the vapor for at least two minutes.

19. The method of claim 14, wherein the multiplicity of molecules comprise H₂O or O₂.

20. The method of claim 14, wherein the multiplicity of molecules comprise organic ligands selected from monodentate ligands, bidentate ligands, and tridentate ligands and their analogs.

21. The method of claim 20, wherein each organic ligand of the multiplicity of molecules comprises one or more functional groups independently selected from oxo, hydroxyl, thiol, nitro, cyanide, isocyanide, sulfinyl, mercapto, sulfo, carboxyl, hydrazine, amino, monoalkylamino, dialkylamino, monoarylamino, diarylamino, alkoxy, aryloxy, haloalkyl, ester, amide, alkoxycarbonyl, acylamino, alkoxycarbonylamino, aryloxycarbonylamino, sulfonylamino, sulfamoyl, carbamoyl, alkylthio, ureido, phosphoramide, or silyl functional groups, or any conjugate or combination thereof.

22. The method of claim 20, wherein the monodentate ligands comprise n-butanol.

23. The method of claim 20, wherein the bidentate ligands comprise diacetone alcohol.

24. The method of claim 14, wherein the modified perovskite material comprises up to 2 wt % or up to 5 wt % of the multiplicity of molecules.

25. The method of claim 14, wherein the ABX₃ metal halide perovskite is doped with A site replacements, B site replacements, or both.

26. The method of claim 14, wherein the A site replacements comprise Li⁺, Na⁺, K⁺, Rb⁺, Cs⁺ and their monoionic analogs, or any combination thereof and wherein the B site replacements comprise Mg²⁺, Ca²⁺, Mn²⁺, Ni²⁺, Cu²⁺, Zn²⁺ and their bivalent analogs, or any combination thereof.

27. A full color display comprising:
an array of red, green, and blue pixels, wherein each pixel comprises:
an anode layer;
a hole injection layer;
a hole transporting layer;
an electron blocking layer;
a blue emissive layer;
a blue hole blocking layer;
an electron transporting layer; and
a cathode layer,
wherein the red pixels further comprise a red color conversion material comprising the modified perovskite material of claim 1 and the green pixels further comprise a green color conversion material comprising the modified perovskite material of claim 1.

28. The full color display of claim 27, further comprising a red color filter on a surface of the red color conversion material, a green color filter on a surface of the green color conversion material, or both.

29. A method of fabricating the full color display of claim 27, the method comprising:
forming an array of blue pixels, each blue pixel comprising:
an anode layer;
a hole injection layer;
a hole transporting layer;
an electron blocking layer;
a blue emissive layer;
a blue hole blocking layer;
an electron transporting layer; and
a cathode layer; and
disposing the red color conversion material on a top of selected semi-transparent electrode (cathode or anode) of a first subset of the blue pixels; and
disposing the green color conversion material on a top of selected semi-transparent electrode (cathode or anode) of a second subset of the blue pixels.

30. The method of claim 29, wherein the blue pixels are formed in the absence of a shadow mask.

31. The method of claim 29, wherein each layer of the blue pixels is fabricated as a common layer comprising the same components.

32. The method of claim 29, wherein disposing the red color conversion material on the first subset of the blue pixels comprises a shadow mask controlled vapor deposition process.

33. The method of claim 29, wherein disposing the green color conversion material on the second subset of the blue pixels comprises a shadow mask controlled vapor deposition process.

34. The method of claim 29, further comprising disposing a red filter on a surface of the red color conversion material, a green filter on a surface of the green color conversion material, or both.

35. The method of claim 34, wherein disposing comprises a photolithographic process.

36. A method of fabricating the full color display of claim 27, the method comprising:
disposing the red color conversion material in first discrete regions on a substrate, thereby defining a location of red pixels;
disposing the green color conversion material in second discrete regions on the substrate, thereby defining a location of green pixels; and
forming blue organic light emitting diodes on the first discrete regions, the second discrete regions, and third discrete regions, wherein the third discrete regions define a location of blue pixels.
